(19) United States
(12) Patent Application Publication
(10) Pub. No.: US 2024/0162210 A1
(43) Pub. Date: May 16, 2024

(54) LIGHT SOURCE MODULE AND LED FILM COMPRISING SAME

(71) Applicant: LG ELECTRONICS INC., Seoul (KR)

(72) Inventors: Baekjun KIM, Seoul (KR); Myeongwook BAE, Seoul (KR); Daewoon HONG, Seoul (KR)

(73) Assignee: LG ELECTRONICS INC., Seoul (KR)

(21) Appl. No.: 18/281,811

(22) PCT Filed: Jul. 7, 2021
(86) PCT No.: PCT/KR2021/008643

§ 371 Date: Sep. 13, 2023

(51) Int. Cl. H01L 25/16; H01L 25/075; H01L 33/62; H05B 45/10; H05B 45/20

(52) U.S. Cl. CPC H01L 25/167; H05B 45/10; H05B 45/20; H01L 25/0753; H01L 33/62

(57) ABSTRACT

A light source module comprises: a base; LED chips mounted on the base and generating light of predetermined colors; a control IC for controlling the operation of the LED chips; and a signal electrode connecting the LED chips and the control IC, wherein two or more LED chips outputting the same color are mounted, and the control IC controls a current value applied to the LED chips outputting the same color to adjust the brightness. The light source module can be used outdoors since a visible distance thereof is increased.

### TECHNICAL FIELD

The present disclosure relates to a light source module including a plurality of LED chips and a control IC that controls the same, and an LED film having the same.

### BACKGROUND

An LED film is a display device in which a light emitting diode (hereinafter, ‘LED’) is installed as a light source on a thin film. The LED film may include multiple LEDs, and may display an intended image by operating the LEDs in response to an operating signal transmitted from the outside. Because of being entirely composed of a film, such LED film may have a thin, light, and flexible structure. In addition, the film of the LED film may be made of a transparent material, and in this case, the LED film may be entirely transparent. Furthermore, the LED film may be coated with an adhesive material. Therefore, the LED film may be easily installed on various types of surfaces for various purposes. For example, the LED film may be installed on a building outer wall or transparent glass regardless of a shape thereof (i.e., a curved surface or a flat surface) to provide predetermined image information including advertisements.

Such an LED film may be configured to realize a color image. In this case, the LEDs of different colors may be formed as one module and multiple modules may be installed on the film. In general, such a module may include a substrate having embedded circuit and electrode and LED chips of different colors installed on the substrate. Each chip is connected to the circuit on the board using a metal wire, and a sealing material is applied on the substrate to protect the chips and the metal wire. Therefore, the module has a complicated structure, and a method for manufacturing the same is likewise complicated. In addition, because of the complicated structure and manufacturing process, the module has a high failure rate and is difficult to maintain. Furthermore, a heat dissipation rate of the LEDs may be lowered because of the complicated structure, and thus, a luminous efficiency of the LEDs may be lowered.

### SUMMARY

### Technical Problem

The present disclosure is to provide a light source module that includes a plurality of LED chips and a control IC that controls the chips, and is able to be used outdoors and is able to adjust brightness based on the night and the day, and an LED film including the same.

### Technical Solutions

Provided is a light source module including a base, an LED chip that is mounted on the base and generates light of a predetermined color, a control IC that controls operation of the LED chip, and a signal electrode connecting the LED chip and the control IC to each other, wherein the LED chip includes two or more LED chips that output the same color, wherein the control IC adjusts brightness by adjusting a current value applied to the LED chips that output the same color.

The LED chip may include a red chip, a green chip, and a blue chip that generate red, green, and blue light, respectively.

The LED chips that output the same color may include a first chip and a second chip, and the control IC may adjust the brightness in 4 stages by applying maximum current or ½ of the maximum current to the first chip.

The control IC may control the LED chip in one of the stages including a first stage of applying the ½ of the maximum current to the first chip, a second stage of applying the maximum current to the first chip, a third stage of applying the maximum current to the first chip and applying the ½ of the maximum current to the second chip, and a fourth stage of applying the maximum current to the first chip and the second chip.

The control IC may control the LED chip in one of the stages including a first stage of applying the ½ of the maximum current to the first chip, a second stage of applying the ½ of the maximum current to the first chip and the second chip, a third stage of applying the maximum current to the second chip and applying the ½ of the maximum current to the first chip, and a fourth stage of applying the maximum current to the first chip and the second chip.

The LED chips that output the same color may be distributed on both sides around the control IC.

The LED chips that output the same color may be arranged in a point-symmetric manner around a center of the light source module.

The LED chip may include a white chip, a red chip, a green chip, and a blue chip that generate white, red, green, and blue light, respectively.

The white chip may improve the brightness by being applied with current together when the red chip, the green chip, and the blue chip operate.

The LED chip may include a red chip, a green chip, and a blue chip that generate red, green, and blue light, respectively, and three white chips that are respectively paired with the red chip, the green chip, and the blue chip and generate white light, and the paired white chip may be applied with current to operate when the red chip, the green chip, and the blue chip operate.

Provided is a light source module including a base, an LED chip that is mounted on the base and generates light of a predetermined color, a control IC that controls operation of the LED chip, and a signal electrode connecting the LED chip and the control IC to each other, wherein the LED chip includes a white chip, a red chip, a green chip, and a blue chip that generate white, red, green, and blue light, respectively, wherein the white chip improves brightness by being applied with current together when the red chip, the green chip, and the blue chip operate.

The white chip may include three white chips respectively paired with the red chip, the green chip, and the blue chip, and the paired white chip may be applied with the current to operate when the red chip, the green chip, and the blue chip operate.

Provided is an LED film including a transparent film, a plurality of light source modules arranged in a grid on the transparent film, and a main electrode that is disposed on the transparent film and supplies an operating signal and power to the light source module, wherein the light source module includes a base, an LED chip that is mounted on the base and generates light of a predetermined color, a control IC that controls operation of the LED chip, and a signal electrode connecting the LED chip and the control IC to each other, wherein the LED chip includes two or more LED chips that output the same color, wherein the control IC adjusts brightness by adjusting a current value applied to the LED chips that output the same color.

### Advantageous Effects

The LED film using the light source module with the increased light quantity may be used outdoors as the viewing distance is increased.

In addition, because the brightness of the light source module may be adjusted, the brightness may be adjusted based on the night and the day, thereby solving the problem of light pollution.

In addition, as the number of LED chips controlled by one control IC increases, the number of control ICs to realize the same brightness may be reduced.

### BRIEF DESCRIPTION OF THE DRAWINGS

FIGS. 1 to 2 are diagrams showing examples of a display device according to an embodiment of the present disclosure.

FIG. 3 is a perspective view showing a light source module according to the present disclosure.

FIG. 4 shows a plan view and a side view of a light source module in FIG. 3.

FIG. 5 is a diagram showing another embodiment of a light source module.

FIG. 6 is a diagram for illustrating a data packet structure of a control IC and a current control method for controlling a light source module.

FIGS. 7 and 8 are diagrams showing a method for controlling a light source module.

FIGS. 9 to 11 are diagrams showing another embodiment of a light source module according to the present disclosure and a data packet structure of a control IC for controlling the light source module.

### DETAILED DESCRIPTION

Exemplary embodiments disclosed herein, with reference to the accompanying drawings. For the sake of brief description with reference to the drawings, the same or equivalent components may be provided with the same reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In the present disclosure, that which is well-known to one of ordinary skill in the relevant art has generally been omitted for the sake of brevity. The accompanying drawings are used to help easily understand various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, when an element is referred to as being “directly connected with” another element, there are no intervening elements present.

A singular representation may include a plural representation unless it represents a definitely different meaning from the context.

Terms such as “include” or “has” are used herein and should be understood that they are intended to indicate an existence of several components, functions or steps, disclosed in the specification, and it is also understood that greater or fewer components, functions, or steps may likewise be utilized.

Hereinafter, an LED (light emitting diode) panel ill be described as an example of a display panel, but the display panel applicable to the present disclosure may not be limited to the LED panel, and may also include an organic display panel (organic light emitting diode, OLED), a plasma display panel (PDP), a field emission display panel (field emission display, FED), or a liquid crystal display (LCD).

Embodiments described herein relate to a light source module of an LED film. However, it will be readily apparent to those skilled in the art that a principle and a configuration of the described embodiments may be substantially equally applied to all light source modules using LEDs.

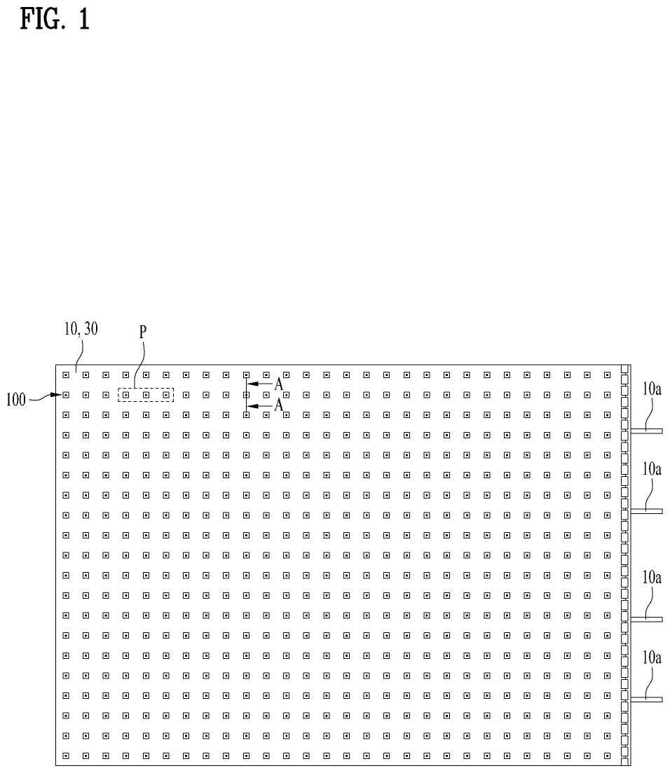

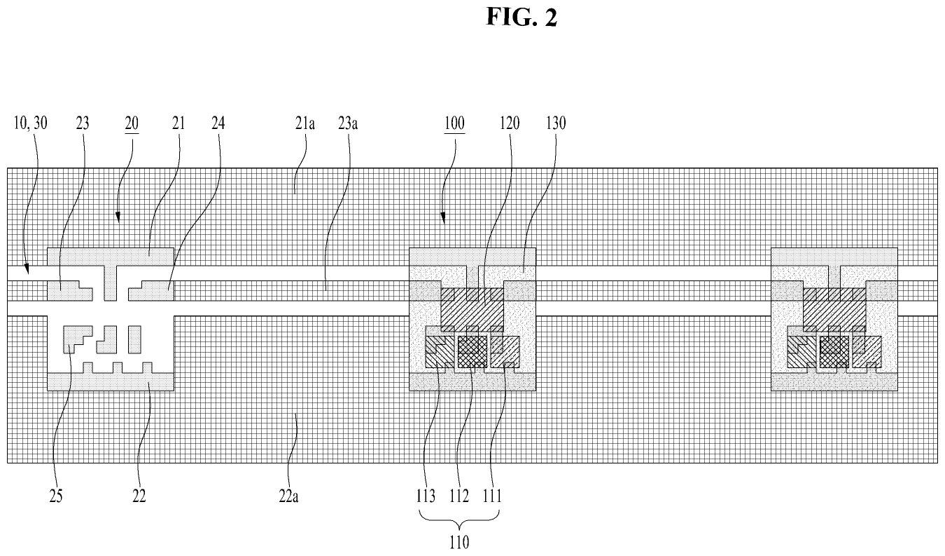

FIG. 1 is a plan view showing an LED film according to the present disclosure, and FIG. 2 is a partially enlarged view showing an area P in FIG. 1.

Referring to FIGS. 1 and 2 first, the LED film according to the present disclosure may include a film 10 of a predetermined size. The film 10 may function as a platform on which other parts of the LED film are mounted, and may have various sizes depending on a purpose. The film 10 may have a small thickness and may be made of a light and flexible material, for example, one of various flexible polymer compounds. Therefore, the LED film may be easily deformed because of such characteristics of the film 10, and thus, may be easily attached to surfaces of various shapes, for example, a surface having a predetermined curvature. In addition, the film 10 may be made of a transparent material, and thus, the entire LED film may be transparent.

Because such transparent LED film does not reduce transparency of an attached area thereof, the transparent LED film may also be applied to a glass window of a building. In addition, when the transparent LED film is applied to the glass window, a displayed image may be viewed via the glass window. The film 10 may include a terminal 10a installed at one end thereof.

The terminal 10a may be connected to an external device and an external power source, and may also be connected to internal parts of the LED film. Accordingly, the terminal 10a may receive an operating signal, that is, a video signal and power (or a voltage) from the external device and the power source, and supply the operating signal to the internal parts.

For example, the terminal 10a may be composed of a flexible body and multiple circuits disposed within the body, that is, a flexible PCB or a film PCB, and may be easily connected to the external device and the power source while being deformed by flexibility thereof.

In addition, as well shown in FIG. 2, the LED film may include a main electrode 20 disposed on the film 10. The main electrode 20 may be formed of a thin layer made of a conductive material, and may have a predetermined pattern suitable for transmitting power and a signal to a predetermined part, that is, a light source module 100 to be described later.

More specifically, the electrode 20 may include a first power electrode 21 that supplies + power or voltage and a second power electrode 22 that supplies − power or voltage. In addition, the electrode 20 may include a first signal electrode 23 that inputs data, that is, the operating signal, and a second signal electrode 24 for outputting the operating signal. The first and second signal electrodes 23 and 24 may be connected to a control integrated circuit) IC 120 to be described later for controlling operation of the light source module 100. In addition, to control operation of an LED chip 100 to be described later, the control IC 120 may also be connected to the chip 100 by a connection electrode 25 of the electrode 20.

In one example, the electrode 20 may be connected to the terminal 10a by intermediate electrodes 21a, 22a, and 23a to receive external power and signals. As shown in FIG. 2, the intermediate electrodes 21a, 22a, and 23a may be composed of a thin mesh member and may extend along the film 10 from the electrode 20 to the terminal 10a.

In the electrode 20, the power, signal, and connection electrodes 21 to 25 may be exposed to the outside of the film 10 for connection with the light source module 100, but the intermediate electrodes 21a, 22a, and 23a may be embedded within the film 10 so as to be protected.

As shown in FIG. 1, multiple pixels, that is, the light source modules 100, may be required for the LED film to realize an intended image, and accordingly, multiple electrodes 20 respectively corresponding to the multiple light source modules 100 may be disposed on the film 10. Accordingly, the intermediate electrodes 21a, 22a, and 23a may connect multiple electrodes 20 adjacent to each other, particularly, electrodes 20 included in the same row to each other.

More specifically, the first intermediate electrode 21a may connect first power source electrodes 21, which are adjacent to each other, to each other, and the second intermediate electrode 22a may connect second power source electrodes 22, which are adjacent to each other, to each other. Accordingly, power supplied to the terminal 10a may be simultaneously supplied to the multiple first and second power electrodes 21 and 22 by the first and second intermediate electrodes 21a and 22a.

In addition, the third intermediate electrode 23a may connect the first and second signal electrodes 23 and 24, which are adjacent to each other, to each other, and accordingly, the operating signal supplied from the terminal 10a may be relayed via the multiple electrodes 20 via repetition of input/output by the signal electrodes 23 and 24.

The LED film may also include the light source module 100 for emitting light. The light source module 100 may emit light by the operating signal and the power, and may be connected to the main electrode 20 to receive required signal and power. Because a loss may occur when a connection path between the electrode 20 and the module 100 is long, to shorten such a connection path, the light source module 100 may be directly disposed on and connected to the main electrode 20, as shown in FIG. 2.

As described above, the multiple pixels are required in the LED film to realize the intended image. Accordingly, each of the light source modules 100 may function as one pixel, and the multiple light source modules 100 may be respectively disposed on the corresponding electrodes 20 as shown in FIG. 1. In addition, such light source modules 100 may be spaced apart from each other at a regular spacing to form one matrix for a high quality image.

Referring to FIG. 2, the light source module 100 may basically include an LED chip 110 for emitting light of a predetermined color. The LED chip 110 may include a substrate and semiconductor layers stacked on the substrate and emitting light by applied power or voltage. To supply the power or the voltage to the semiconductor layers, the LED chip 110 may include electrodes connected to the semiconductor layers. In addition, the LED film may realize the color image using the light source module 100. In this case, the LED chip 110 may include multiple LED chips 111a, 111b, 112a, 112b, 113a, and 113b for generating light of different colors. For example, the LED chip 110 may include the first chips 111a and 111b that generate blue light, the second chips 112a and 112b that generate red light, and the third chips 113a and 113b that generate red light.

In addition, the light source module 100 may include the control IC 120 for controlling the operation of the LED chip 110. The control IC 120 may control the operation of the LED chip 100 by controlling the power and the signal supplied via the electrode 20, and accordingly, the light source module 100, more precisely, the LED chip 110 may generate light of an intended color.

Because the LED chip 110 and the control IC 120 perform a single intended function, that is, a function of a single pixel, the LED chip 110 and the control IC 120 may be structurally formed as one module. In the LED film according to the present disclosure, the modularization may be achieved using a base 130 that supports the chip 110 and the IC 120 and couple the chip 110 and the IC 120 to each other at the same time.

Such type of LED film may be installed on the glass window or a glass wall, so that the LED film may be transparent when the image is not output, and the image may be viewed on both surfaces when the image is output. Although the LED film may be installed indoors, the LED film may also be installed on an outer wall of a building or outdoors. When the LED film is installed on the outer wall or outdoors, the LED film may not be seen well during the day. When the LED film is installed outdoors, brightness thereof needs to be different during the day and night, so that an LED film that may adjust the brightness is needed.

The light source module 100 may become each pixel of the LED film, and one image may be output via the LED film by adjusting a color and brightness of each light source module 100.

The smaller the size of the light source module 100, the higher the resolution of the output image, but the brightness decreases, and when the brightness is weak, a viewing distance is shortened. Therefore, to improve the brightness of the light source module 100 without greatly increasing the size of one light source module 100, that is, each pixel, the present disclosure includes an additional LED chip 110 instead of including only one red LED chip 110, only one blue LED chip 110, and only one green LED chip 110 in one light source module 100 to improve the brightness of each light source module 100.

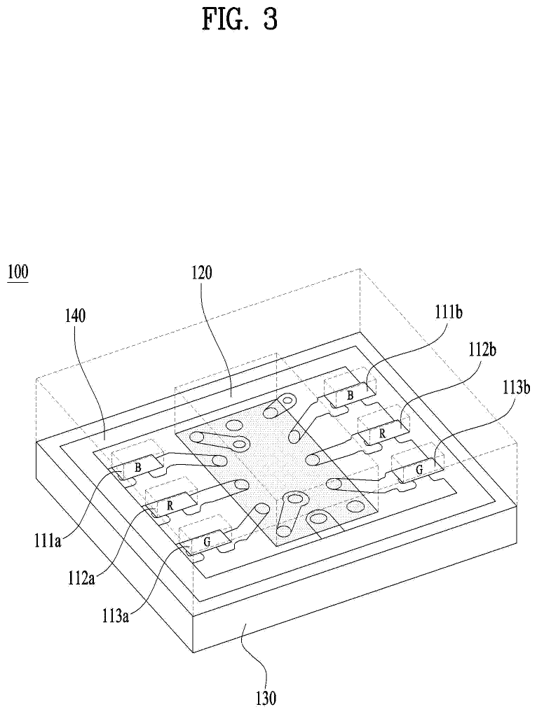

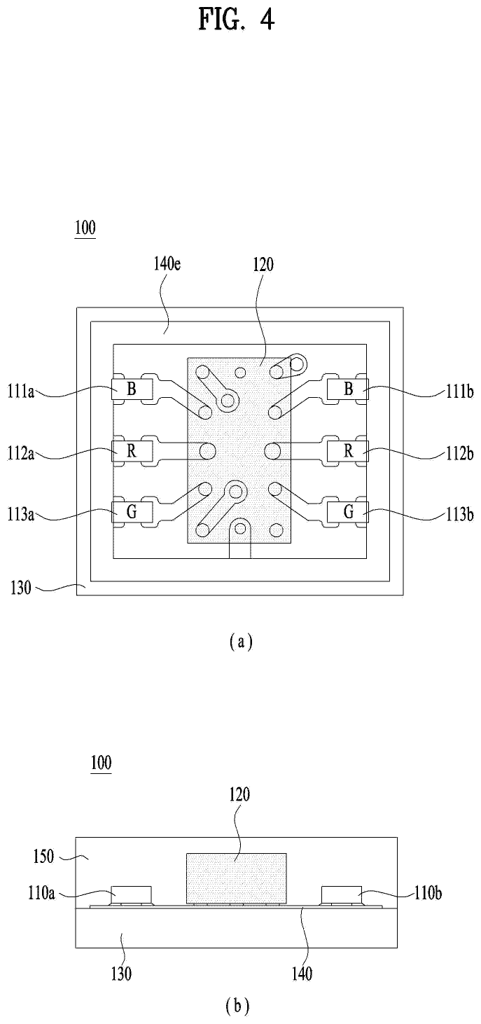

FIG. 3 is a perspective view showing the light source module 100 according to the present disclosure, (a) in FIG. 4 is a plan view of a light source module in FIG. 3, and (b) in FIG. 4 is a side view of the light source module 100. The light source module 100 of the present embodiment may include the base 130, the LED chip 110 and the control IC 120 mounted on the base 130, and a signal line 140 for transmitting and receiving the signal between the LED chip and the control IC 120.

The signal line 140 may be printed on one surface of the base 130, and the control IC 120 and the LED chip 110 may be mounted thereon. The LED chip 110 may include blue chips 111a and 111b, red chips 112a and 112b, and green chips 113a and 113b that may render blue, red, and green colors.

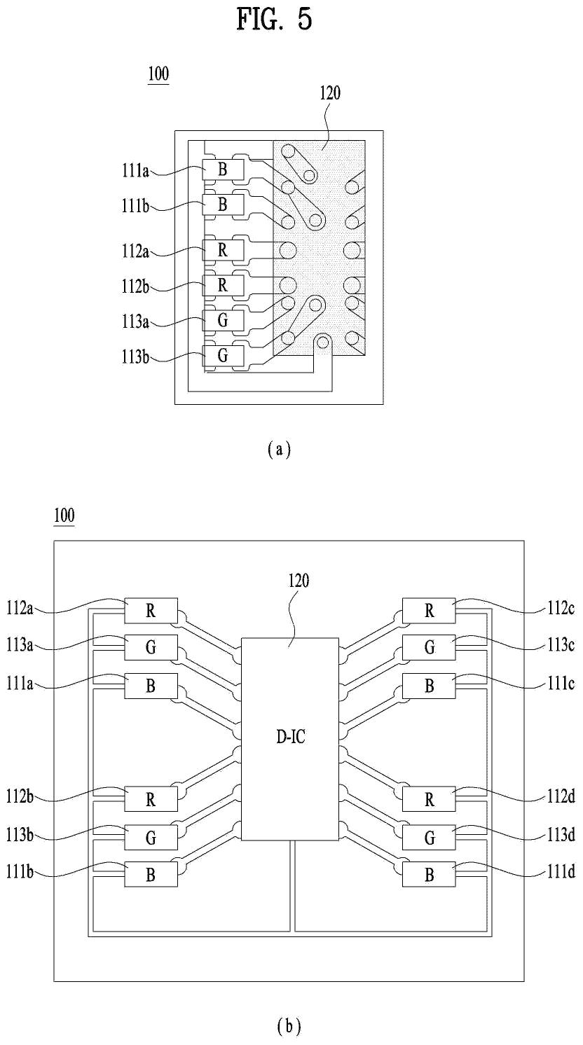

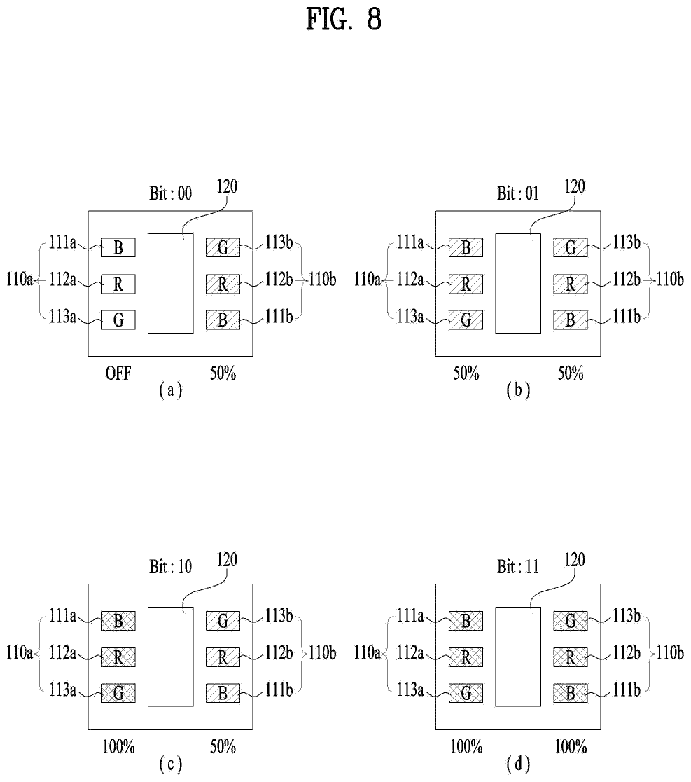

Although FIG. 3 shows an embodiment in which the blue chips 111a and 111b, the red chips 112a and 112b, and the green chips 113a and 113b are arranged in order from the top, and chips of the same color are arranged to be adjacent to each other on left and right sides in a horizontal direction, but the order/arrangement of the LED chips 110 may be changed. As shown in (b) in FIG. 5, the red chips 112a and 112b, the green chips 113a and 113b, and the blue chips 111a and 111b may be arranged in order. Alternatively, as shown in FIG. 8, LED chips 111a and 110b of the same color may be arranged in a point-symmetric manner so as to be most spaced apart from each other instead of being arranged in a bilaterally symmetric manner (see FIG. 8).

The LED chips 110 in the present embodiment form a pair for each color. Brightness of a light source may be increased using a plurality of LED chips 110 of the same color in one light source module 100. When the number of LED chips 110a and 110b controlled by one control IC 120 increases instead of using two light source modules 100 for one pixel, the number of control ICs 120 may be reduced.

An intensity of light emitted from each light source module 100 may be relatively uniform by arranging the LED chips 110 to be distributed on left and right sides of the control IC 120. As shown in (a) in FIG. 5, the LED chips 111a, 111b, 112a, 112b, 113a, and 113b may be disposed to be biased on one side of the control IC 120, but in this case, a right side of the light source module 100, that is, a portion where the control IC 120 is located may look dark, so that it is preferable to arrange the LED chips 111a, 111b, 112a, 112b, 113a, and 113b in a bilaterally symmetrical structure.

When the LED chips are distributed on the left and right sides of the control IC 120 in the light source module 100 as shown in FIG. 3, heat generated during the operation of the light source module 100 may be dispersed, so that durability of the light source module 100 may be improved.

The control IC 120 and the LED chip 110 are of a flip chip type and are able to be joined to each other in a soldering scheme without a separate wire, so that the size of the light source module 100 may be made small. Each LED chip 110 is connected to the control IC 120 via the signal line, and the signal line 140 is formed on the base 130 in a form of a metal foil containing a metal material and thus has high thermal conductivity, which is advantageous in dissipating the heat emitted from the LED chip 110 and the control IC 120.

The control IC 120 may control current applied to each LED chip 110 in response to a control signal. The color and the brightness of each pixel are determined based on an amount of current applied to each LED chip 110.

The light source module 100 may be formed in a rectangular shape with a size equal to or smaller than 2 mm. In the present embodiment, six LED chips 110 and one control IC 120 may be mounted on the base 130 with a width of 1.6 mm and a height of 1.4 mm. Although the size of the LED chip 110 is increased as the number of LED chips 110 is increased compared to the existing light source module 100, the brightness of each pixel may be increased, which enables use outdoors.

An encapsulant 150 that covers and protects the LED chip 110 and the control IC 120 may be made of a material with high transmittance and high reliability. For example, the encapsulant 150 may contain silicon, epoxy, acryl, and the like, and because a thickness of the control IC 120 is greater than that of the LED chip 110, the encapsulant 150 may be formed thicker than the control IC 120.

FIG. 5 is a diagram showing another embodiment of the light source module 100.

As shown in (a) in FIG. 5, six LED chips 111a, 111b, 112a, 112b, 113a, and 113b may be disposed on one side of the control IC 120 as the LED chips 110 are disposed to be located on one side. In this case, compared to the above embodiment, the LED chips 111a, 111b, 112a, 112b, 113a, and 113b may be biased to one side, which may be disadvantageous in terms of heat dissipation, but the size of the light source module 100 may become smaller.

As shown in (b) in FIG. 5, 12 LED chips 111a to 113d may be used. Although there is a disadvantage that the size of the light source module 100 of the present embodiment increases, as the number of LED chips 110 for each color is great, brightness of the image may be adjusted in multi-levels.

Hereinafter, for convenience of description, a description will be made based on the embodiment in FIGS. 3 and 4, which is a basic form.

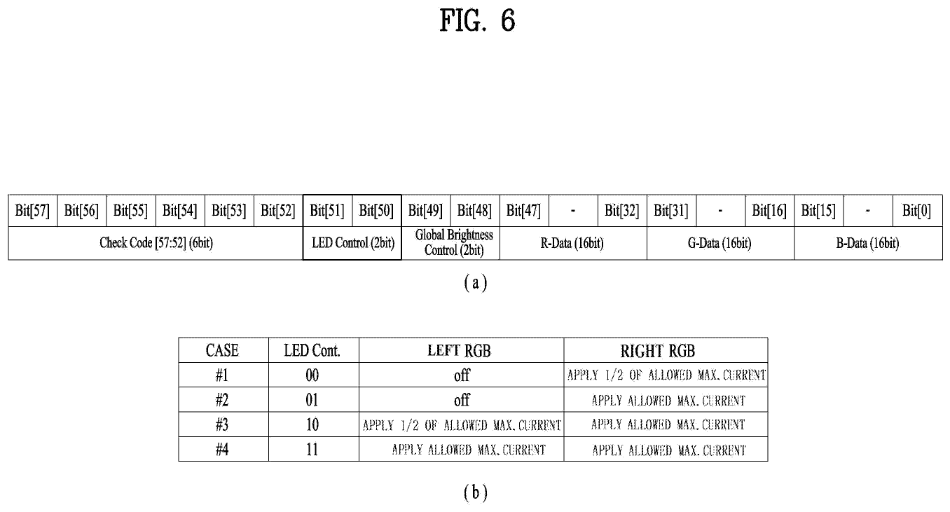

FIG. 6 is a diagram for illustrating a data packet structure of the control IC 120 and a current control method for controlling the light source module 100. (a) shows the data packet structure of the control IC 120, and (b) is a table showing the method for controlling the current applied to each LED chip 110 based on a value of an LED control bit.

A data packet of the control IC 120 may include a check bit (a check code, 6 bit), LED control (2 bit) data that adjusts an amount of current applied to the LED chip 110, global brightness control (2 bit) data, and color data (R-data, G-data, and B-data) including data about operating the LED chip for each color for color reproduction.

The color data includes information on control of each LED chip to reproduce color output by each pixel.

The LED control data includes data for controlling a magnitude of current applied to the LED chip 110 when the number of LED chips 110 for each color is greater than one as in the present disclosure. The 2 bit LED control data may express one of four signals as shown in (b), and may control an amount of current applied to the LED chip 110 to output one of 1/4 brightness of maximum brightness, 2/4 brightness of the maximum brightness, 3/4 brightness of the maximum brightness, and the maximum brightness.

In this regard, the brightness does not refer to exactly the 1/4, 2/4, or 3/4 brightness, but to four levels of the brightness between the maximum brightness and minimum brightness, and does not indicate an absolute magnitude of the brightness.

It is shown that the current is applied such that only LED chips 110 on one side among the LED chips 110 output the maximum brightness at the 2/4 brightness, but ½ current may be equally applied to each pair of LED chips 110 to realize the 2/4 brightness. In addition, the 3/4 brightness of the light source module 100 may be realized by maximizing brightness of the LED chips 110 operating at maximum brightness even at the 3/4 brightness and brightness of the other chips different from the LED chip 110 and operating at 1/4 brightness.

Such a control method may evenly use the plurality of LED chips 110, thereby preventing a life span of a specific LED chip 110 from being shortened, and increasing a life span of the light source module 100.

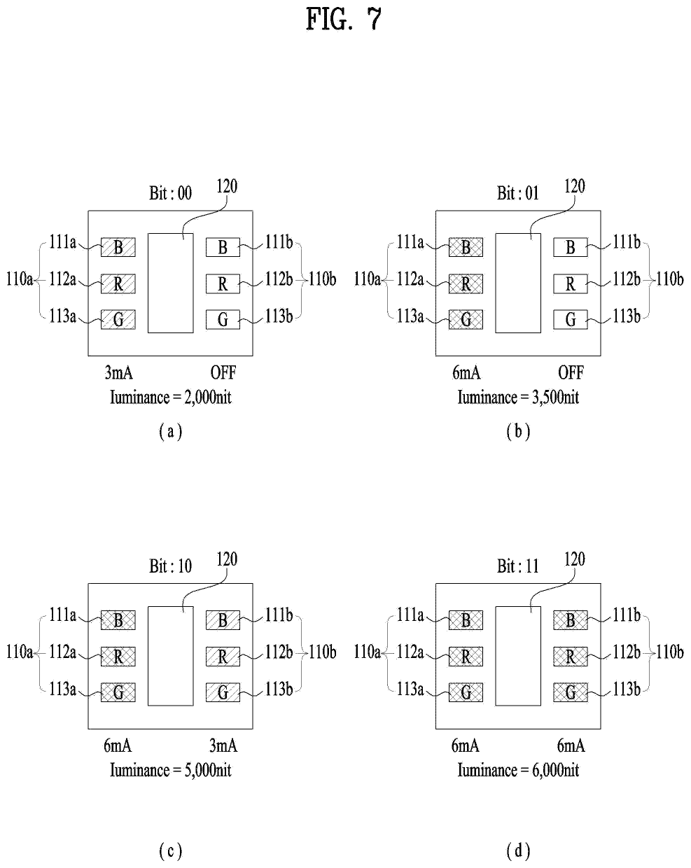

FIGS. 7 and 8 are diagrams showing a method for controlling the light source module 100, and more specifically, shows a method for adjusting the brightness by adjusting the amount of current applied to each LED chip 110 based on the table in (b) in FIG. 6.

Assuming that maximum current applied to one LED chip 110 is 6 mA, in (a) in FIG. 7, when current of 3 mA is applied to left chips 111a, 111ba, 112a, 112ba, 113a, and 113ba, the brightness of the light source module 100 may be about 2000 nits.

As in (b), when current of 6 mA is applied only to the left chips, the light source module 100 may emit light with brightness of 3500 nits greater than the brightness in (a). In addition, as in (c), when one side is applied with the current of 6 mA and the other side is applied with the current of 3 mA, the light source module 100 may operate with brightness of 5000 nits. As shown in (d), when the maximum current is applied to all of the LED chips 110 of the same color, the light source module 100 may emit light with the maximum brightness of 6000 nits.

As shown in FIG. 8, the arrangement of the LED chips 110 may be different from that in FIG. 3. In the case of FIG. 3, chips of the same color are arranged on left and right sides around the control IC 120, but, in the present embodiment, the chips of the same color are arranged in a point-symmetric manner around a center of the light source module 100.

As such, when the chips of the same color are arranged diagonally so as to be most spaced apart from each other within the light source module 100, light may be emitted uniformly within the pixel. In addition, when a specific color is output, because locations of heating portions are spaced apart, damage caused by heat may be reduced.

As described above, when 2/4 current flows to equalize use of the first LED chip 110 and the second LED chip 110, the current may not be applied only to the first LED chip 110 or to the second LED chip 110, but the current of 3 mA may be uniformly supplied to the first LED chip 110 and the second LED chip 110 to achieve an output corresponding to 3500 nits.

That is, the first blue chips 111a and 111b may be located at an upper left end, and the second blue chips 111a and 111b may be located at a lower right end. The first red chips 112a and 112b may be located at the lower left end, the second red chips 112a and 112b may be located at the upper right end, and the green chips 113a and 113b may be disposed on the left and right sides. Alternatively, the blue, red, and green chips may be arranged in order on the left side, and the green, blue, and red chips may be arranged in order on the right side.

When the LED chips 110 of the same color are disposed to be spaced apart from each other, light may be uniformly emitted within the pixel, and it is advantageous in terms of the heat dissipation.

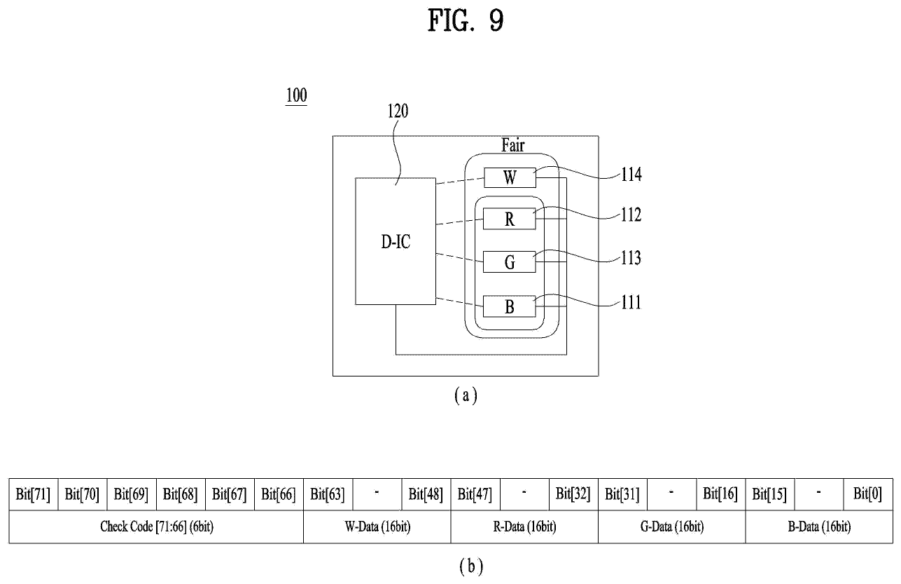

FIGS. 9 to 11 are diagrams showing another embodiment of the light source module 100 according to the present disclosure and a data packet structure of the control IC 120 for controlling the light source module 100. (a) in FIGS. 9 to 11 are diagrams showing various embodiments of the light source module 100 having a white chip, and (b) are diagrams showing the data packet structure of the control IC 120 for controlling the light source module 100 in (a).

As described above, luminance of the light source module 100 may be improved by having several LED chips 110 of the same color, but the luminance may be improved by having a white chip, which is the LED chip 110 that outputs light of a white color as shown in (a) in FIG. 9.

The luminance may be improved by operating the white chip together with the red chips 112a and 112b, the blue chips 111a and 111b, and the green chips 113a and 113b that output light of colors. The embodiment in (a) in FIG. 9 has one white chip 114 paired with the LED chips 110 of the three colors, and the white chip 114 emits light together to increase luminance of the entire LED film.

The white chip may emit light together when the red chips 112a and 112b, the blue chips 111a and 111b, and the green chips 113a and 113b are operated to increase the overall luminance. That is, the luminance may be improved by adding one LED chip 114, thereby minimizing the increase in the size of the light source module 100.

As shown in (b) in FIG. 9, to independently operate the white chip 114 using 16-bit data like other color chips, color data for the white chip (W-data) is added.

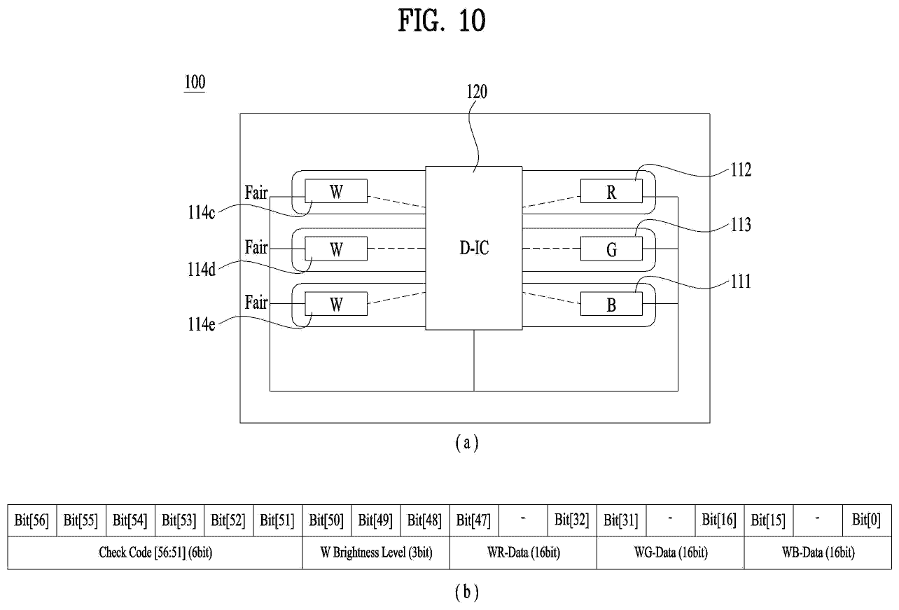

The embodiment shown in (a) in FIG. 10 may include each white chip paired with each color chip, unlike the embodiment in (a) in FIG. 9. As the white chip is operated together when the paired color chip is operated, referring to (b) in FIG. 10, brightness adjustment (W brightness level) data that controls brightness of the white chip is required to operate the white chip, and only 3 bits are added in the existing data packet structure, which enables easy control.

However, there is a disadvantage in that the size of the light source module 100 increases because the number of white chips is greater than that in the embodiment in FIG. 9.

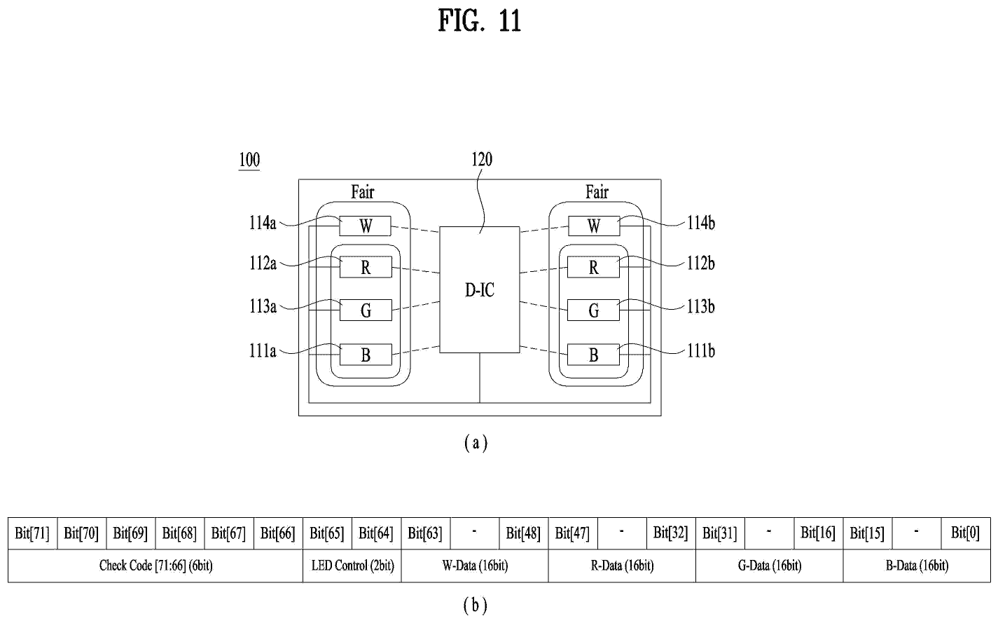

FIG. 11 is an embodiment in which two sets of four LED chips 110 of the white chip, the red chip 112a, the blue chip 111a, and the green chip 113a paired with each other, and the white chip, the red chip 112b, the blue chip 111b, and the green chip 113b paired with each other according to the embodiment in FIG. 9 are included. Because a pair of identical LED chips 110 are disposed as in FIG. 3 above, as shown in (b) in FIG. 11, two bits are added to include LED control data for controlling a magnitude of current applied to the two LED chips 110.

As described above, the LED film using the light source module with increased light quantity may be used outdoors as the viewing distance is increased.

In addition, because the brightness of the light source module may be adjusted, the brightness may be adjusted based on the night and day, thereby solving a problem of light pollution.

In addition, as the number of LED chips controlled by one control IC increases, the number of control ICs to realize the same brightness may be reduced.

The above detailed description should not be construed as being limitative in all terms, but should be considered as being illustrative. The scope of the present invention should be determined by reasonable analysis of the accompanying claims, and all changes in the equivalent range of the present invention are included in the scope of the present invention.

What is claimed is:

1. A light source module comprising:
a base;
an LED chip mounted on the base and configured to generate light of a predetermined color;
a control IC configured to control operation of the LED chip; and
a signal electrode connecting the LED chip and the control IC to each other,
wherein the LED chip includes two or more LED chips configured to output the same color,
wherein the control IC is configured to adjust brightness by adjusting a current value applied to the LED chips configured to output the same color.

2. The light source module of claim 1, wherein the LED chip includes a red chip, a green chip, and a blue chip configured to generate red, green, and blue light, respectively.

3. The light source module of claim 1, wherein the LED chips configured to output the same color include a first chip and a second chip,
wherein the control IC is configured to adjust the brightness in 4 stages by applying maximum current or ½ of the maximum current to the first chip.

4. The light source module of claim 3, wherein the control IC is configured to control the LED chip in one of the stages including:
a first stage of applying the ½ of the maximum current to the first chip;
a second stage of applying the maximum current to the first chip;
a third stage of applying the maximum current to the first chip and applying the ½ of the maximum current to the second chip; and
a fourth stage of applying the maximum current to the first chip and the second chip.

5. The light source module of claim 3, wherein the control IC is configured to control the LED chip in one of the stages including;
a first stage of applying the ½ of the maximum current to the first chip;
a second stage of applying the ½ of the maximum current to the first chip and the second chip;
a third stage of applying the maximum current to the second chip and applying the ½ of the maximum current to the first chip; and
a fourth stage of applying the maximum current to the first chip and the second chip.

6. The light source module of claim 1, wherein the LED chips configured to output the same color are distributed on both sides around the control IC.

7. The light source module of claim 1, wherein the LED chips configured to output the same color are arranged in a point-symmetric manner around a center of the light source module.

8. The light source module of claim 1, wherein the LED chip includes a white chip, a red chip, a green chip, and a blue chip configured to generate white, red, green, and blue light, respectively.

9. The light source module of claim 8, wherein the white chip is configured to improve the brightness by being applied with current together when the red chip, the green chip, and the blue chip operate.

10. The light source module of claim 1, wherein the LED chip includes a red chip, a green chip, and a blue chip configured to generate red, green, and blue light, respectively, and three white chips respectively paired with the red chip, the green chip, and the blue chip and configured to generate white light,
wherein the paired white chip is applied with current to operate when the red chip, the green chip, and the blue chip operate.

11. A light source module comprising:
a base;
an LED chip mounted on the base and configured to generate light of a predetermined color;
a control IC configured to control operation of the LED chip; and
a signal electrode connecting the LED chip and the control IC to each other,
wherein the LED chip includes a white chip, a red chip, a green chip, and a blue chip configured to generate white, red, green, and blue light, respectively,
wherein the white chip is configured to improve brightness by being applied with current together when the red chip, the green chip, and the blue chip operate.

12. The light source module of claim 11, wherein the white chip includes three white chips respectively paired with the red chip, the green chip, and the blue chip,
wherein the paired white chip is applied with the current to operate when the red chip, the green chip, and the blue chip operate.

13. An LED film comprising:
a transparent film;
a plurality of light source modules arranged in a grid on the transparent film; and
a main electrode disposed on the transparent film and configured to supply an operating signal and power to the light source module,
wherein the light source module includes:
a base;
an LED chip mounted on the base and configured to generate light of a predetermined color;
a control IC configured to control operation of the LED chip; and
a signal electrode connecting the LED chip and the control IC to each other,
wherein the LED chip includes two or more LED chips configured to output the same color,
wherein the control IC is configured to adjust brightness by adjusting a current value applied to the LED chips configured to output the same color.

14. The LED film of claim 13, wherein the LED chips configured to output the same color include a first chip and a second chip,
wherein the control IC is configured to adjust the brightness in 4 stages by applying maximum current or ½ of the maximum current to the first chip.
